(19) United States
(12) Patent Application Publication
(10) Pub. No.: US 2026/0348838 A1
(43) Pub. Date: Nov. 5, 2026

(54) ARTIFICIAL INTELLIGENCE COMPOSITE MIXTURE DETECTION SYSTEM BASED ON THERMAL EMISSION CHIP AND CONSTRUCTION METHOD THEREFOR

(71) Applicant: Nanjing University, Nanjing (CN)

(72) Inventors: Hui Liu, Nanjing (CN); Xiaohe Shang, Nanjing (CN); Fan Zhong, Nanjing (CN); Ye Zhang, Nanjing (CN); Jinguang Shang, Nanjing (CN); Kai Gao, Nanjing (CN); Yanling Xiao, Nanjing (CN); Qiang Wang, Nanjing (CN); Chong Sheng, Nanjing (CN); Xinjie Lv, Nanjing (CN); Shining Zhu, Nanjing (CN)

(21) Appl. No.: 19/555,990

(22) Filed: Mar. 4, 2026

(30) Foreign Application Priority Data
Mar. 4, 2025 (CN) 202510250317.9

(51) Int. Cl. G01N 21/25; G01N 21/35; G01N 21/3577; G06F 30/20; G06N 3/0464

(52) U.S. Cl. CPC G01N 21/255; G01N 21/3577; G06F 30/20; G06N 3/0464; G01N 2021/3595; G01N 2201/12761; G01N 2201/1296; G01N 2201/13

(57) ABSTRACT

Disclosed are an artificial intelligence composite mixture detection system based on a thermal emission chip and a construction method therefor, relating to field of infrared detection technology. The disclosure first prepares a thermal emission chip, and constructs an artificial intelligence model, then, the thermal emission chip is heated, and thermography data produced by passing thermal emission emitted by the thermal emission chip through the different standard samples are acquired by the infrared camera, and finally, the thermography data of the different standard samples are input into the artificial intelligence model, to adjust a parameter of the artificial intelligence model, to train the artificial intelligence model. In the technical solution, infrared thermography data are processed using the trained artificial intelligence model, enabling to detect a component of a sample and predict concentration of the component, improving system precision and sensitivity in identifying a composite mixture, improving detection efficiency and correctness.

### CROSS-REFERENCE TO RELATED APPLICATIONS

This application claims the benefit of and priority to Chinese patent application no. 202510250317.9, filed on Mar. 4, 2025, the contents of which are hereby incorporated by reference herein in their entirety.

### TECHNICAL FIELD

The present disclosure relates to the field of infrared detection technology, and in particular, to an artificial intelligence composite mixture detection system based on a thermal emission chip and a construction method therefor.

### BACKGROUND

In recent years, infrared thermography and spectral detection technology based on a metasurface with micro-nanostructures and on artificial intelligence has received extensive attention. Introduction of a metasurface and application of infrared thermography technology provide new direction for improving infrared detection system performance.

Infrared absorption spectroscopy detection is a technique that analyzes composition and physical properties of a material by measuring absorption intensity of the material for infrared light of different wavelengths. Infrared spectroscopy is capable of providing rich information on chemical composition, molecular structure, and material state, and applies widely to chemical analysis, environmental monitoring, and medical diagnosis. Since different materials have specific infrared absorption characteristics, composition and physical change of a material may be identified and analyzed effectively using infrared spectral data.

A metasurface is an artificial material consisting of subwavelength micro-nanostructures, exhibiting a unique capability of controlling electromagnetic waves. By designing the shape, size, and arrangement of structural units (such as nanopillars, nanoantennas, etc.) thereof, a metasurface enables to accurately control electromagnetic waves in the infrared band. With development of nanomanufacturing technology, metasurface technology demonstrating an increasingly wide range of promising applications in infrared spectroscopy and thermal emission control. An efficient infrared absorption chip may be designed using a metasurface, providing a new solution for infrared thermography, temperature detection, etc.

Infrared thermography technology detects infrared light radiated by an object, and converts it into an image, to display object temperature distribution. This technology is widely applied in fields such as healthcare, industrial inspection, environmental monitoring, etc. By combining a metasurface with micro-nanostructures, a modern infrared thermography system may achieve superior absorption and radiation performance across different infrared bands, thereby improving system sensitivity and precision. Current conventional and mainstream infrared substance detection technology mainly focuses on substance identification and quantitative analysis using spectral analysis. Fourier transform infrared spectroscopy (FTIR) technology remains one of the most widely used methods thereof. A FTIR system emits an infrared beam through a high-precision optical device such as a Michelson interferometer, a tunable laser, a blackbody radiation source, etc., to irradiate a sample to be tested. A substance absorbs infrared light of a specific wavelength, forming a characteristic absorption spectrum. Characteristic peaks of the spectrum are closely related to chemical composition and structure of the substance, and are capable of providing accurate substance identification and quantitative analysis. FTIR technology commonly applies to a plurality of fields such as gas analysis, food safety, environmental monitoring, pharmaceutical industry, etc. In a conventional FTIR system, a key to obtaining high-quality spectral data lies in using a stable infrared light source with sufficient intensity, particularly in a sensitive mid-infrared (MIR) region in the infrared band. A FTIR system typically provides broad-spectrum infrared light using a blackbody radiation source, adjusts a phase of the light source using a Michelson interferometer, to resolve the spectrum via interference. Through absorption characteristics of the infrared detection spectrum, the chemical composition of the sample may be determined, which applies widely to qualitative and quantitative substance analysis. Although FTIR technology is applied widely in substance analysis, there are some limitations. First, limited spectral resolution may lead to overlapping peaks in a complex sample, impacting analytical precision. Second, there is a high requirement on sample preparation, wherein a solid or viscous sample requires special treatment, which may lead to a measurement error. Additionally, moisture produces interference in infrared absorption spectroscopy, wherein especially in the mid-infrared band, a water absorption peak may overlap with a characteristic peak of a target substance. Devicewise, a FTIR system is high-cost, and requires regular maintenance, increasing economic burdens and technical barriers. Finally, absorption spectra of some samples are indistinct or overlap, making quantitative analysis difficult. Although these technologies provide high spectral resolution, their sensitivity and resolution remain inadequate when dealing with a composite mixture or a trace component. Therefore, there is a pressing need for designing a method capable of accurately detecting a substance composition of a product without requiring spectroscopic measurement. Moreover, despite employing a filter with a metasurface, some systems still require an additional infrared light source, thereby increasing system cost and complexity.

### SUMMARY

One objective of the present disclosure is to provide a construction method for an artificial intelligence composite mixture detection system based on a thermal emission chip, solving a technical problem of spectral overlap between substance components of a mixture in prior art.

Another objective of the present disclosure is to provide an artificial intelligence composite mixture detection system based on a thermal emission chip.

Specifically, the present disclosure provides a construction method for an artificial intelligence composite mixture detection system based on a thermal emission chip, the method including:
preparing a thermal emission chip, and constructing an artificial intelligence model based on the thermal emission chip;
sequentially placing different standard samples between the thermal emission chip and an infrared camera, and heating the thermal emission chip, such that the infrared camera acquires reaction signal data produced when thermal emission emitted by the thermal emission chip is absorbed by the respective different standard samples; and
inputting the reaction signal data of the different standard samples into the artificial intelligence model, to adjust a parameter of the artificial intelligence model, to train the artificial intelligence model.

Optionally, the method further includes: after the preparing a thermal emission chip, and constructing an artificial intelligence model based on the thermal emission chip, heating the thermal emission chip, and acquiring background signals for the thermal emission chip not originating from the standard samples;
correcting reaction signals of the different standard samples using the background signals, to obtain the corrected reaction signal data;
training the artificial intelligence model using the corrected reaction signal data, to obtain a trained model.

Optionally, the artificial intelligence model is constructed by:
constructing a first Conv1D layer, the first Conv1D layer being configured to extract local features of the corrected reaction signal data;
constructing a MaxPooling1D layer, the MaxPooling1D layer being configured to perform dimensionality reduction on the local features;
constructing a second Conv1D layer, the second Conv1D layer being configured to enhance capability of extracting the local features;
flattening, using a Flatten layer, two-dimensional feature maps of the local features into a one-dimensional vector;
constructing a Dense layer, the Dense layer being configured to integrate feature information of the local features; and
constructing an output layer, the output layer being configured to output detection results for components of the standard samples and prediction results of concentrations of the components.

Optionally, the thermal emission chip is prepared by:
constructing a model of a metasurface array;
simulating the model of the metasurface array using a simulation software, to obtain a target thickness parameter of a respective layer of material in the model of the metasurface array; and
preparing the thermal emission chip based on the target thickness parameter of the respective layer of material.

Optionally, the preparing the thermal emission chip based on the target thickness parameter of the respective layer of material specifically includes:
providing a substrate;
depositing a metal layer on the substrate, wherein the metal layer serves as a reflective substrate;
sequentially preparing a spacer layer and a silicon layer on the metal layer through magnetron sputtering or chemical vapor deposition, wherein the spacer layer is located between the metal layer and the silicon layer; and
performing micro-nanofabrication on the silicon layer using lithography or etching processes, thereby preparing and obtaining the thermal emission chip having the metasurface array.

Optionally, the performing micro-nanofabrication on the silicon layer using lithography or etching processes, thereby preparing and obtaining the thermal emission chip having the metasurface array specifically includes:
simulating a period of the metasurface array on the silicon layer and diameters and heights of silicon nanopillars using the simulation software, to select a target period as well as target diameters and target heights of the silicon nanopillars; and
performing micro-nanofabrication on the silicon layer using lithography or etching processes based on the target period as well as the target diameters and the target heights of the silicon nanopillars, thereby preparing and obtaining the thermal emission chip having the metasurface array.

Optionally, in the inputting the reaction signal data of the different standard samples into the artificial intelligence model, to adjust a parameter of the artificial intelligence model, to train the artificial intelligence model, the corrected reaction signal data are divided into a training set and a test set, wherein the training set is configured to train the artificial intelligence model, and the test set is configured to test the artificial intelligence model.

Specifically, the present disclosure further provides an artificial intelligence composite mixture detection system based on a thermal emission chip, applied to the aforementioned construction method, the system including:
a heating device;
a thermal emission chip, provided on one side of the heating device, wherein the thermal emission chip is configured to generate, when heated by the heating device, infrared thermal emission signals having preset radiation characteristics;
an infrared camera, provided on a side of the thermal emission chip facing away from the heating device, wherein a standard sample is placed between the thermal emission chip and the infrared camera, and the infrared camera is configured to acquire a signal produced by an absorption reaction between the infrared thermal emission signals and the standard sample, and process the signal to generate data packets; and
an artificial intelligence model based on the thermal emission chip, provided on a side of the infrared camera facing away from the thermal emission chip, wherein the artificial intelligence model is configured to receive the data packets, detect a component of the standard sample based on the data packets, and predict a concentration of the component.

The present disclosure first prepares a thermal emission chip, and constructs an artificial intelligence model, then, different standard samples are sequentially placed between the thermal emission chip and an infrared camera, and the thermal emission chip is heated, such that the infrared camera acquires thermography data produced by passing thermal emission emitted by the thermal emission chip through the different standard samples, and finally, the thermography data of the different standard samples are input into the artificial intelligence model, to adjust a parameter of the artificial intelligence model, to train the artificial intelligence model. In the aforementioned technical solution, thermography data of different standard samples are used to train an artificial intelligence model, to process infrared thermography data using the trained artificial intelligence model, which enables to detect a component of a sample to be tested and predict concentration of the component, improving system precision and sensitivity in identifying a composite mixture, improving detection efficiency and correctness.

Based on the detailed description of embodiments of the present disclosure below made combining the drawings, those skilled in the art will gain a clearer understanding of the aforementioned and other objectives, advantages, and features of the present disclosure.

### BRIEF DESCRIPTION OF DRAWINGS

Specific embodiments of the present disclosure are elaborated below with reference to the drawings in an illustrative non-limiting manner. Identical reference signs denote identical or similar components or parts in the drawings. Those skilled in the art should understand that these drawings are not necessarily drawn to scale. In the drawings:

FIG. 1 is a flowchart of a construction method for an artificial intelligence composite mixture detection system based on a thermal emission chip according to an embodiment of the present disclosure;

FIG. 2 is a flowchart of a construction method for an artificial intelligence composite mixture detection system based on a thermal emission chip according to another embodiment of the present disclosure;

FIG. 3 is a flowchart of a construction method for an artificial intelligence composite mixture detection system based on a thermal emission chip according to yet another embodiment of the present disclosure;

FIG. 4. is a diagram of a structure of an artificial intelligence composite mixture detection system based on a thermal emission chip according to an embodiment of the present disclosure;

FIG. 5 is a diagram of a structure for a thermal emission chip according to an embodiment of the present disclosure;

FIG. 6 is a diagram of infrared absorption spectra of a thermal emission chip according to an embodiment of the present disclosure;

FIG. 7 is a diagram of infrared transmission spectra of methanol, ethanol, and acetone measured using FTIR according to an embodiment of the present disclosure;

FIG. 8 is a diagram of obtaining characteristic temperature data of methanol, ethanol, and acetone using an artificial intelligence composite mixture detection system based on a thermal emission chip according to an embodiment of the present disclosure;

FIG. 9 is a diagram of a confusion matrix for categorizing methanol, ethanol, and acetone using an artificial intelligence composite mixture detection system based on a thermal emission chip according to an embodiment of the present disclosure;

FIG. 10 is a diagram of a confusion matrix for categorizing 50 samples with different mixing ratios using an artificial intelligence composite mixture detection system based on a thermal emission chip according to an embodiment of the present disclosure;

FIG. 11 is a diagram of results of predicting methanol concentration using an artificial intelligence composite mixture detection system based on a thermal emission chip according to an embodiment of the present disclosure;

FIG. 12 is a diagram of results of predicting ethanol concentration using an artificial intelligence composite mixture detection system based on a thermal emission chip according to an embodiment of the present disclosure;

FIG. 13 is a diagram of results of predicting acetone concentration using an artificial intelligence composite mixture detection system based on a thermal emission chip according to an embodiment of the present disclosure.

### REFERENCE SIGNS

100-detection system, 200-standard sample, 10-heating device, 20-thermal emission chip, 30-infrared camera, 40-artificial intelligence model.

### DETAILED DESCRIPTION OF THE EMBODIMENTS

Embodiments of the present disclosure are elaborated below, and examples of the embodiments are illustrated in the drawings, throughout which identical or similar reference signs denote identical or similar elements or elements with identical or similar functions. Embodiments described below with reference to the drawings are illustrative, for explaining the present disclosure, and should not be construed as limiting the scope of the present disclosure.

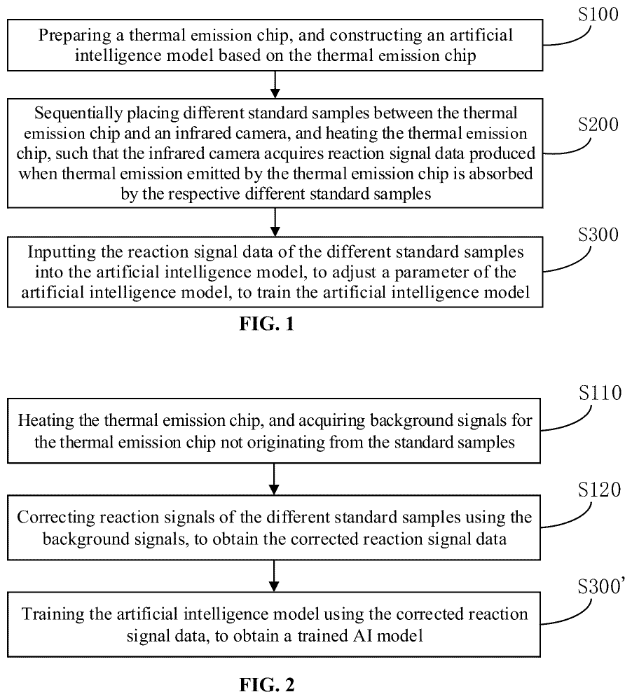

FIG. 1 is a flowchart of a construction method for an artificial intelligence composite mixture detection system based on a thermal emission chip according to an embodiment of the present disclosure. As shown in FIG. 1, in a specific embodiment, the construction method for an artificial intelligence composite mixture detection system based on a thermal emission chip includes steps as follows.

S100, Preparing a thermal emission chip, and constructing an artificial intelligence model based on the thermal emission chip

S200, Sequentially placing different standard samples between the thermal emission chip and an infrared camera, and heating the thermal emission chip, such that the infrared camera acquires thermography data produced by passing thermal emission emitted by the thermal emission chip through the different standard samples

S300, Inputting the reaction signal data of the different standard samples into the artificial intelligence model, to adjust a parameter of the artificial intelligence model, to train the artificial intelligence model

In the embodiment, thermography data of different standard samples are used to train an artificial intelligence model, to process infrared thermography data using the trained artificial intelligence model, which enables to improve precision and sensitivity in identifying a composite mixture, and to detect a component of a target sample and predict concentration of the component.

In the embodiment, on one hand, thermal emission signals are generated by heating the thermal emission chip, enabling substance detection by combining infrared thermography and the trained artificial intelligence model. Heating the thermal emission chip provides a low-cost and stable infrared light source, which replaces expensive lasers and blackbody radiation sources, significantly reduces system cost, and achieves miniaturization and integration, solving the problem of a conventional infrared spectroscopy system being bulky in volume and of poor portability. On the other hand, processing infrared thermography data using the trained artificial intelligence model improves system precision and sensitivity in identifying a composite mixture, improving detection correctness.

In an artificial intelligence model training phase, a metasurface chip is first heated through a heating platform, to generate infrared thermal emission with specific spectral characteristics. When the infrared thermal emission passes through a standard sample, radiation signals of different wavelengths undergo absorption reactions with the standard sample, wherein the infrared camera integrates these signals, to capture overall change in the radiation after passing through the standard sample, wherein recorded data includes comprehensive information about absorption characteristics of the standard sample.

In the embodiment, by training using measurement data of a series of standard samples, combining characteristics of the radiation from the thermal emission chip, a one-dimensional convolutional neural network (1D-CNN) based model is developed, implementing substance classification and concentration prediction for a sample. After data acquisition and preprocessing, the thermography data are input into the convolutional neural network for analysis and processing.

Specifically, the convolutional neural network model includes: a one-dimensional convolutional layer, employing 64 convolutional kernels (kernel size 3), with ReLU as an activation function, for extracting local features of a sample; feature dimensionality reduction is then performed by a pooling layer (pool size 2); a second convolutional layer includes 128 convolutional kernels (kernel size 3), to further enhance feature extraction capability. Flattened features are input into a fully connected layer with 128 neurons, then, overfitting is prevented by a Dropout layer (dropout rate 0.4), and finally, substance classification and concentration prediction are achieved by an output layer of a linear activation function and a fully connected layer with 64 neurons. In a substance classification task, the convolutional neural network model extracts key features from spectral data through multi-layer convolution and feature extraction operation, to finally output category information of the sample accurately. Classification results are visualized through a confusion matrix, demonstrating classification accuracy and analyzing potential misclassification, thereby ensuring reliability and accuracy of the classification results. In a concentration prediction task, the convolutional neural network model establishes a mapping relationship between spectral features and sample component concentrations through deep learning of the spectral data, and outputs specific concentration values (for example, A%, B%, C%) of respective components. Concentration prediction results are evaluated through the mean squared error (MSE) and the determination coefficient (R²), to verify prediction precision of the model across different concentration ranges.

In the embodiment, through training and optimization with standard sample data, the artificial intelligence model, that is, the convolutional neural network model, is enabled to effectively implement two core functions of substance classification and concentration prediction for a sample, significantly improving an intelligence level and practical application capability of the detection system.

FIG. 2 is a flowchart of a construction method for an artificial intelligence composite mixture detection system based on a thermal emission chip according to another embodiment of the present disclosure. As shown in FIG. 2, after S100, steps as follows are further included.

S110, Heating the thermal emission chip, and acquiring background signals for the thermal emission chip not originating from the standard samples

S120, Correcting reaction signals of the different standard samples using the background signals, to obtain the corrected reaction signal data

S300′, Training the artificial intelligence model using the corrected reaction signal data, to obtain a trained model

In the embodiment, correcting the reaction signals using the background signals may improve correctness of the reaction signal data, and thereby better training the artificial intelligence model. In the training process of the artificial intelligence model, the background signals not originating from (i.e., without passing through) the standard samples are first recorded, for subsequent background correction. After that, micro-nanostructures of the thermal emission chip are activated and radiation characteristics thereof recorded. Transmitted light intensities of air and the standard samples are then measured, to obtain system baseline data and radiation characteristics data of the standard samples, respectively. All measurements are repeated to ensure data correctness. After background correction, the transmittance of the standard samples is calculated, thereby obtaining reliable standard sample signal data, for training the artificial intelligence model.

Through accurate background correction and standardized data preprocessing, as well as a broad-spectrum signal generation mechanism based on the thermal emission chip, the construction method of the embodiment significantly reduces impact of external interference on the detection results, ensuring high correctness and repeatability of data. By combining the infrared camera and an efficient detection flow with the artificial intelligence model, the embodiment enables rapid substance classification and concentration prediction for a sample to be tested, features high efficiency and low cost, and has a wide range of promising applications in rapid detection and intelligent analysis across a plurality of fields such as material detection, composition analysis, and environmental monitoring.

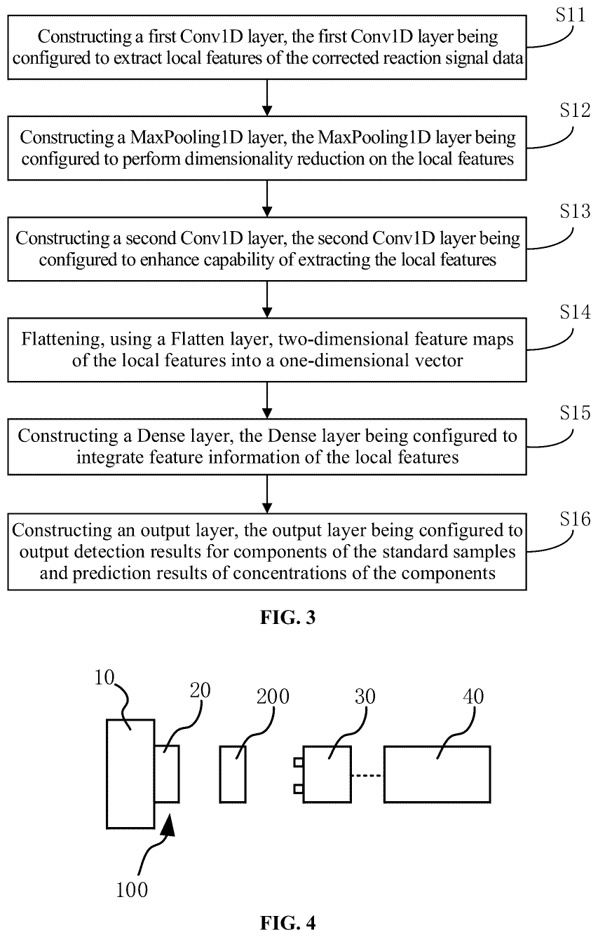

FIG. 3 is a flowchart of a construction method for an artificial intelligence composite mixture detection system based on a thermal emission chip according to yet another embodiment of the present disclosure. As shown in FIG. 3, the artificial intelligence model is constructed through steps as follows.

S11, Constructing a first Conv1D layer, the first Conv1D layer being configured to extract local features of the corrected reaction signal data

S12, Constructing a MaxPooling1D layer, the MaxPooling1D layer being configured to perform dimensionality reduction on the local features

S13, Constructing a second Conv1D layer, the second Conv1D layer being configured to enhance capability of extracting the local features

S14, Flattening, using a Flatten layer, two-dimensional feature maps of the local features into a one-dimensional vector

S15, Constructing a Dense layer, the Dense layer being configured to integrate feature information of the local features

S16, Constructing an output layer, the output layer being configured to output detection results for components of the standard samples and prediction results of concentrations of the components

In some embodiments, a metasurface chip is prepared through steps as follows.
Step 1, Constructing a model of a metasurface array
Step 2, Simulating the model of the metasurface array using a simulation software, to obtain a target thickness parameter of a respective layer of material in the model of the metasurface array
Step 3, Preparing the thermal emission chip based on the target thickness parameter of the respective layer of material
In Step 2, parameters such as a metal layer, a spacer layer, heights of silicon nanopillars, etc., may be adjusted as variables in the simulation software: for example, the metal layer may range from 50 nm to 150 nm in thickness, the spacer layer is set to range from 50 nm to 150 nm in thickness, and the silicon nanopillars may be adjusted to range from 300 nm to 800 nm in height. In these adjustments, by systematically scanning parameter combinations for the layers, impact on electromagnetic resonance modes and absorption peak positions is observed, thereby identifying an optimal layer thickness combination, ensuring efficient and precise absorption and radiation control within a target infrared band.

In some embodiments, the preparing the thermal emission chip based on the target thickness parameter of the respective layer of material specifically includes steps as follows.
Step 4, Providing a substrate
Step 5, Depositing a metal layer on the substrate, wherein the metal layer serves as reflective substrate
Step 6, Sequentially preparing a spacer layer and a silicon layer on the metal layer through magnetron sputtering or chemical vapor deposition, wherein the spacer layer is located between the metal layer and the silicon layer
Step 7, Performing micro-nanofabrication on the silicon layer using lithography or etching processes, thereby preparing and obtaining the thermal emission chip having the metasurface array
Following the step 7, i.e., after thermal emission chip fabrication, cleaning and drying processes are performed, to remove impurities and ensure surface cleanliness. It should be noted that the design method of the embodiment is not limited to the aforementioned fabrication process, and a plurality of flexible process technologies, such as nanoimprint lithography, electron beam lithography, etc., may be employed for thermal emission chip manufacture, to adapt to different preparation requirements and conditions. Through the aforementioned process flow, a periodic metasurface array located on top of the spacer layer and the metal layer is obtained.

In some embodiments, Step 7 specifically includes steps as follows.
Step 8, Simulating a period of the metasurface array on the silicon layer and diameters and heights of silicon nanopillars using the simulation software, to select a target period as well as target diameters and target heights of the silicon nanopillars
Step 9, Performing micro-nanofabrication on the silicon layer using lithography or etching processes based on the target period as well as the target diameters and the target heights of the silicon nanopillars, thereby preparing and obtaining the thermal emission chip having the metasurface array

In the embodiment, the thermal emission chip is constructed through the aforementioned steps, achieving efficient thermal emission control within the mid-infrared band (7-12 μm). A thermal emission chip design philosophy lies in using electromagnetic characteristics of the metasurface structure, placing the silicon nanopillar array on top of the spacer layer and the metal layer, and accurately controlling multipole resonance modes such as an electric dipole (ED), a magnetic dipole (MD), etc., by optimizing geometric parameters (for example, cylinder diameter, height, and period), thereby improving absorption and radiation performance within a specific wavelength range. Additionally, by adjusting a proportional parameter (scaling factor s) of the geometric dimensions of the metasurface chip, absorption peak positions may be flexibly tuned, to meet requirements of different application scenarios.

Specifically, start from a silicon nanopillar diameter D set to 0.6 times period P, wherein for example, a period P of 10 μm is selected, and then, the diameter D is 6 μm. The metasurface chip includes, from bottom to top, a 70-nm-thick metal layer, a 100-nm-thick indium tin oxide (ITO) layer, and 600-nm-high silicon nanopillars; based on a silicon dioxide substrate, a complete structural model is built in a simulation software such as COMSOL, initial parameters are set to period P=10 μm, diameter D=6 μm, height 600 nm, etc., and after that, parameter scanning is performed. By adjusting dimensions such as the heights, the diameters, and the period of the silicon nanopillars, electric field distribution and multipole resonance response within a 8-12 μm infrared band are simulated, focusing on observing excitation case of modes such as the electric dipole (ED) and the magnetic dipole (MD). After each adjustment, absorptance is calculated using a formula A=1−R combining reflectance spectral data measured by a Fourier transform infrared spectrometer (FTIR), and simulation results are compared with experimental results. Iterative optimization is performed on the geometric parameters, and the period, diameter ratios, or heights are adjusted, until efficient and precise absorption peak coverage is achieved within a target wavelength band, ensuring that absorption characteristics meet desired requirements, to ultimately determine optimal parameters of the silicon nanopillars.

Although the embodiment uses the silicon nanopillars as basic units, the manufacturing process is not limited to a cylindrical shape. By adjusting design and processing parameters, metasurface structures with other shapes, such as square pillars, conical pillars, and elliptical pillars, may be fabricated. These micro-nanostructures with different shapes may also excite specific electromagnetic resonance modes, achieving efficient absorption and radiation control within the target wavelength band. Selecting different geometric shapes not only expands design flexibility, but also further optimizes spectral response characteristics, to meet increasingly diverse application requirements.

The scaling factor s is defined as a proportional factor for silicon pillar dimensions, based on the optimized geometric parameters. For example, when s=1.4, the initial period P=10 μm and diameter D=6 μm are scaled to be P′=14 μm and D′=8.4 μm, respectively, with height 600 nm unchanged. Different s values (such as 1.2, 1.4, 1.6, etc.) are introduced into the simulation software, progressively observing peak position shift in absorption spectra and change in resonance modes. Simulation results show that when s=1.4, array resonance at wavelength around 8.5 μm is mainly driven by electric dipole mode, with the absorption peak progressively covering the entire 8-12 μm fingerprint region. An s value asjustment step size is further refined (1, 1.2, 1.4, . . . , 2.6) based on simulation data, to accurately match the position of a target absorption peak and optimize absorption intensity. After each adjustment, a final design is calibrated through simulation verification combining FTIR experimental measurements, to ensure that the metasurface array chip achieves desired infrared absorption performance and dynamically tunable characteristics under the adjusted geometric dimensions.

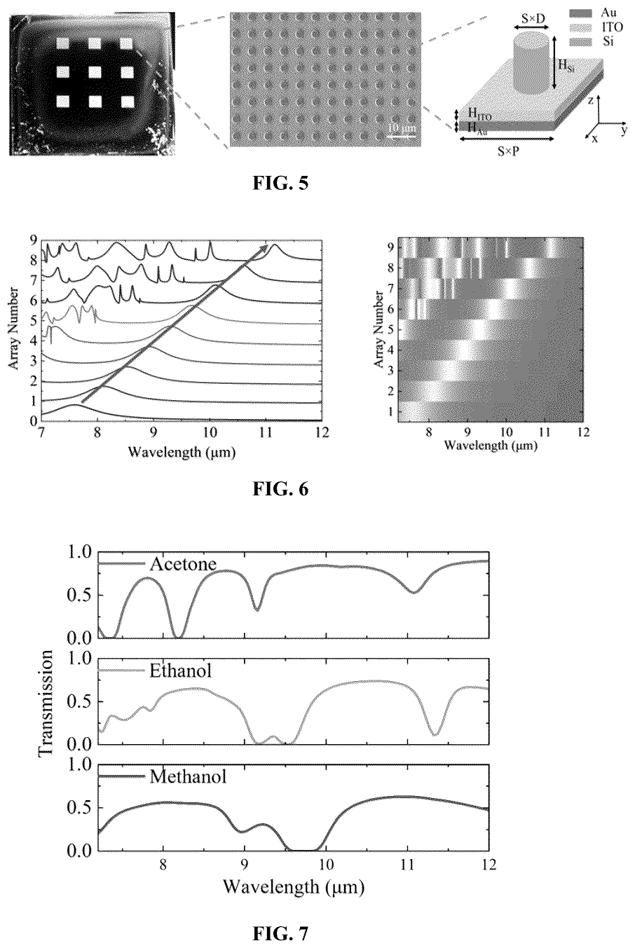

FIG. 5. is a diagram of a structure for a thermal emission chip 20 according to an embodiment of the present disclosure. As shown in FIG. 5, from left to right are diagrams of the thermal emission chip 20, individual metasurface and structural unit, clearly demonstrating multilayer structure of the thermal emission chip 20 and morphology of the silicon nanopillar array from micro-nanofabrication. FIG. 6 is a diagram of infrared absorption spectra of a thermal emission chip 20 according to an embodiment of the present disclosure. Shown on the left in FIG. 6 is the infrared absorption spectra of the metasurface array, highlighting a trend of a resonance peak varying with the structural scaling factor, wherein simulation indicates that the metasurface array exhibits unique absorption characteristics in the mid-infrared band, with significant difference in absorption intensity across different wavelengths. Across different array dimensions and periods, the absorption peak may be precisely tuned and cover the 7-12 μm range. This cylindrical structure may be decomposed into different electromagnetic resonance modes, including the electric dipole (ED), the magnetic dipole (MD), an electric quadrupole (EQ), and a magnetic quadrupole (MQ). Shown on the right in FIG. 5 is a heatmap of the absorption intensity for the metasurface array with different scaling factors s, visually reflecting distribution of absorption performance across the entire mid-infrared band. Overall dimension is adjusted by simultaneously scaling the diameters of the silicon nanopillars and the period by the same proportion, refers to as the scaling factor s. Simulation results indicate that as the scaling factor s increases, a resonance peak dominated by the electric dipole shifts toward longer wavelengths.

Contribution of each mode to total absorptance is analyzed using a multi-level decomposition method, and the simulation results show that an electric dipole scattering mode is a main absorption contributor, which indicates that at this wavelength, the electric field inside the silicon nanopillars induces a significant nonuniform charge distribution, leading to strong electric dipole resonance, forming a distinct absorption peak.

In S300′, the corrected reaction signal data are divided into a training set and a test set, wherein the training set is configured to train the artificial intelligence model 40, and the test set is configured to test the artificial intelligence model 40.

The embodiment implements complex chemical mixture detection by generating thermal emission signals through metasurface heating, and combining a convolutional neural network model and an infrared camera 30. As a tunable thermal emission source, a metasurface provides a stable and broad-spectrum infrared optical signal in the mid-infrared band, covering characteristic absorption by substances such as volatile organic compounds. By acquiring the radiation signals passing through the sample using the infrared camera 30, and processing and analyzing radiation data in real time with the help of the convolutional neural network model, the embodiment proposes an integrated, miniaturized, and low-cost solution, capable of being applied to fields such as environmental monitoring and industrial control, in place of a conventional Fourier transform infrared spectroscopy (FTIR) system.

Compared to prior art, improvement by the embodiment mainly lies in use of a metasurface thermal emission source, in place of a conventional expensive and complex infrared light source (such as a blackbody radiation source or a tunable laser), thereby significantly reducing system cost. Second, replacing the Michelson interferometer in the FTIR with the infrared camera 30 simplifies the system structure, improving miniaturization and integration capabilities. Meanwhile, the radiation data are analyzed and processed combining the convolutional neural network model, improving system capability and sensitivity of composite mixture identification. The improvement significantly reduces overall cost and maintenance requirements of the system, enabling a wider range of promising practical applications thereof.

The embodiment further provides an artificial intelligence composite mixture detection system 100 based on a thermal emission chip 20, applied to the construction method of any of the aforementioned embodiments. As shown in FIG. 4, the composite mixture detection system 100 includes a heating device 10, a thermal emission chip 20, an infrared camera 30, and an artificial intelligence model 40. The thermal emission chip 20 is provided on one side of the heating device 10, wherein the thermal emission chip 20 is configured to generate, when heated by the heating device 10, infrared thermal emission signals having preset radiation characteristics. The infrared camera 30 is provided on a side of the metasurface chip facing away from the heating device 10, wherein a standard sample 200 is placed between the thermal emission chip 20 and the infrared camera 30, and the infrared camera 30 is configured to acquire a signal produced by an absorption reaction between the infrared thermal emission signals and the standard sample 200, and process the signal to generate data packets. The artificial intelligence model 40 is provided on a side of the infrared camera 30 facing away from the thermal emission chip 20, wherein the artificial intelligence model 40 is configured to receive the data packets, detect a component of the standard sample 200 based on the data packets, and predict a concentration of the component.

During the detection, a sample to be tested is placed on an optical path of the thermal emission chip 20. The thermal emission chip 20 is heated by the heating device 10 to generate a broad-spectrum infrared thermal emission signal. When this signal passes through the sample to be tested, radiation of different wavelengths undergoes specific absorption reactions with the sample. The infrared camera 30 captures and records the change in the radiation that has passed through the sample, and generates multi-dimensional data including sample characteristics. After background correction and standardized preprocessing, the acquired to be tested data are input into a trained one-dimensional convolutional neural network (1D-CNN) model, for implementing the two core functions of substance classification and concentration prediction.

During substance classification, the 1D-CNN model extracts key features from the spectral data through deep convolution, to precisely identify and determine category information of the sample. Classification results are visualized through a confusion matrix, intuitively reflecting classification accuracy of respective categories, and analyzing potential misclassification cases, to ensure reliability and correctness of the results. During concentration prediction, the 1D-CNN model establishes a nonlinear mapping relationship between spectral features and component concentrations through deep learning of the spectral data, and ultimately outputs specific concentration values (for example, A %, B %, C %) of respective components. Prediction results are quantitatively evaluated through metrics such as the mean squared error (MSE) and the determination coefficient (R²), and prediction precision and robustness of the model across different concentration ranges are further verified combining error distribution analysis.

In the embodiment, by combining the metasurface and the infrared camera 30, complex elements that are bulky in volume such as the Michelson interferometer in the FTIR system are abandoned, implementing high integration and miniaturization. The infrared camera 30 is compact in volume and capable of acquiring thermal emission signals in real time, and conventional spectrometers with bulky structure are replaced with signal processing and analysis combining artificial intelligence (AI) technology, making the entire system suitable for scenarios that are demanding for volume and integration, such as those with portable devices, industrial sensing nodes, etc.

The embodiment introduces AI technology, and is capable of efficiently processing the thermal emission signals acquired by the infrared camera 30, to automatically analyze the complex radiation data. The convolutional neural network may rapidly classify and identify mixture components, and perform precise component concentration prediction. This significantly improves system capability of handling complex samples, and enables to deal with a multi-component mixture with highly overlapping characteristics, solving difficulty in identification with conventional art when facing a complex spectrum. Thermal emission generated by the metasurface spans the broad spectral band of the mid-infrared spectrum, and is capable of effectively detecting spectral information from a molecular “fingerprint region”. Combining signal processing capability of AI technology, the system may implement high precision detection of a plurality of substances without compromising sensitivity, particularly for trace component identification. This enables the system to deliver exceptional performance in mixture analysis in complex environments, making it suitable for a plurality of fields such as environmental monitoring, material identification, industrial quality control, etc.

The embodiment proposes a substance classification method based on a thermal emission chip 20 for thermal emission and a convolutional neural network (1D-CNN) model, capable of efficiently classifying 50 different substances.

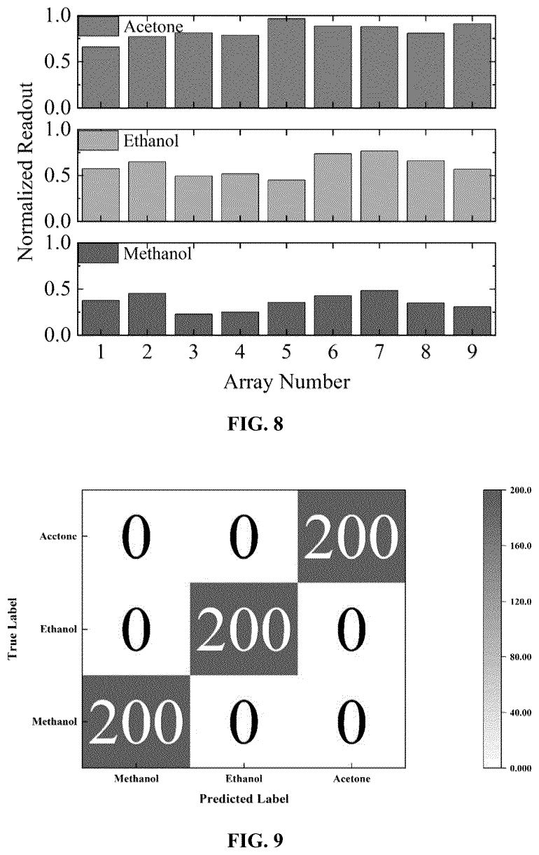

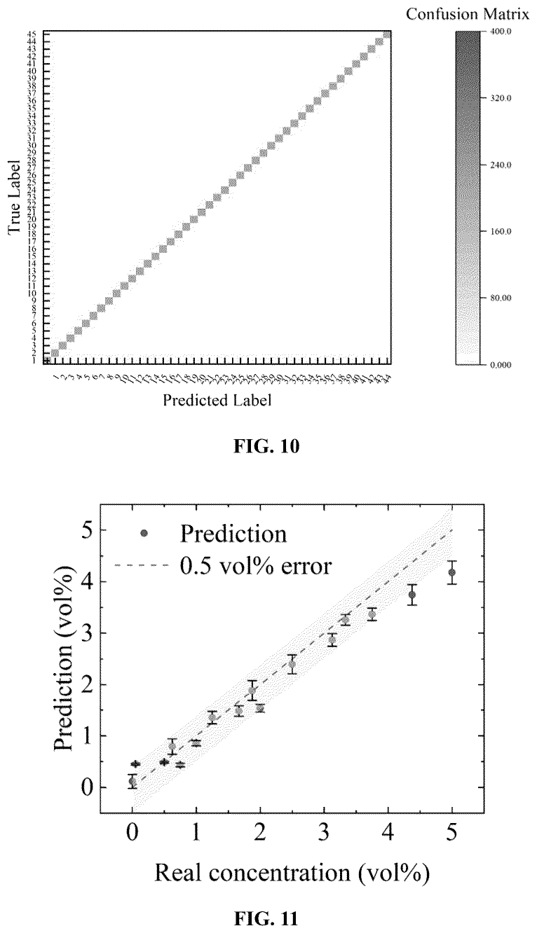

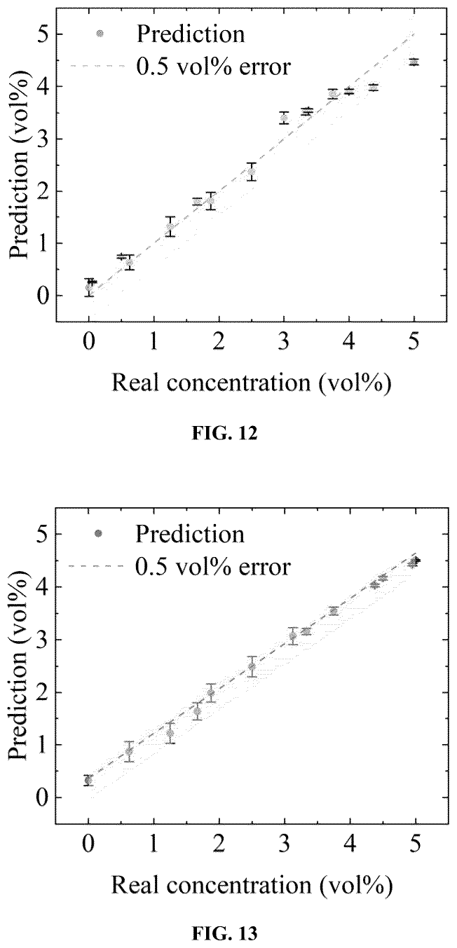

FIG. 7 is a diagram of infrared transmission spectra of methanol, ethanol, and acetone measured using FTIR according to an embodiment of the present disclosure. FIG. 8 is a diagram of obtaining characteristic temperature data of methanol, ethanol, and acetone using an artificial intelligence composite mixture detection system 100 based on a thermal emission chip 20 according to an embodiment of the present disclosure. FIG. 9 is a diagram of a confusion matrix for categorizing methanol, ethanol, and acetone using an artificial intelligence composite mixture detection system 100 based on a thermal emission chip 20 according to an embodiment of the present disclosure. FIG. 10 is a diagram of a confusion matrix for categorizing 50 samples with different mixing ratios using an artificial intelligence composite mixture detection system 100 based on a thermal emission chip 20 according to an embodiment of the present disclosure. FIG. 11 is a diagram of results of predicting methanol concentration using an artificial intelligence composite mixture detection system 100 based on a thermal emission chip 20 according to an embodiment of the present disclosure. FIG. 12 is a diagram of results of predicting ethanol concentration using an artificial intelligence composite mixture detection system 100 based on a thermal emission chip 20 according to an embodiment of the present disclosure. FIG. 13 is a diagram of results of predicting acetone concentration using an artificial intelligence composite mixture detection system 100 based on a thermal emission chip 20 according to an embodiment of the present disclosure. Referring to FIG. 7, FIG. 7 shows infrared transmission spectra of three pure substances (methanol, ethanol, and acetone), with data from Fourier transform infrared spectroscopy (FTIR) measurement. The horizontal axis represents wavelength (μm), and the vertical axis represents transmittance. Each substance exhibits different absorption peaks within a specific wavelength range, which is due to different intramolecular vibrational modes, causing absorption of light with specific wavelengths. These characteristic peaks in the transmission spectra serve as key basis for substance identification, applicable to distinguishing different chemical components. Results of conventional substance detection, i.e., spectroscopic measurement by FTIR, may serve as a reference standard. Our target is to acquire characteristic temperature data of the radiation for identification using the artificial intelligence composite mixture detection system 100 based on a thermal emission chip 20, without relying on any conventional spectrometers. This is also one of the core innovations of the research.

Referring to FIG. 8, FIG. 8 shows infrared characteristic temperature data acquired through the detection device developed by the inventor, wherein the column bar charts corresponds to methanol, ethanol, and acetone, respectively. Compared to the transmission spectra measured by FTIR, data here are based on response of substances to the infrared thermal emission. Specifically, our detection system 100 utilizes a heated infrared metasurface as the radiation source. Different substances exhibit different absorption characteristics for the infrared radiation, leading to differences in their temperature imaging at the infrared camera 30. By analyzing these temperature characteristic data, we may train a classification model using a machine learning method, thereby implementing automatic substance identification. This process breaks free from high cost of conventional FTIR spectroscopy, enabling low-cost, portable infrared detection solutions.

Referring to FIG. 9, FIG. 9 shows machine learning model based classification results, for single-component samples (that is, pure samples of methanol, ethanol, and acetone). Of the confusion matrix, the horizontal axis represents model predicted labels, and the vertical axis represents true labels. Values in the matrix represent sample counts, for example, “200” on the diagonal means 200 samples are classified correctly. Since all non-zero values are strictly distributed along the diagonal, it indicates that the model achieves 100% classification accuracy for the three substances, that is, all test samples are correctly classified. This shows that the convolutional neural network model has successfully captured substance characteristics in the infrared thermal emission data, implementing accurate substance identification.

In further experiments, we study 50 samples with different mixing ratios, acquire data using the same infrared thermography method, and then perform classification through the trained neural network model. FIG. 10 shows classification results for the mixture samples. Compared to pure substance classification, complexity increases here, as characteristics of the mixture samples may be closer, indistinguishable. However, the results of the confusion matrix show that predicted values are still distributed along the diagonal, indicating the neural network classification model maintains a high accuracy even when dealing with composite mixtures. This result demonstrates feasibility of this detection method in mixture systems, laying a foundation for subsequent quantitative concentration prediction.

Referring to FIG. 11, FIG. 11 shows the concentration prediction results of methanol across 50 samples with different mixing ratios. The horizontal axis represents the real concentration (vol %), and the vertical axis represents model predicted concentration (vol %). The distribution of data points shows predictive performance of the model. The dashed line represents an ideal linear fit relationship, that is, predicted values should closely match actual values. Error bars represent uncertainty of the model prediction or fluctuation between the samples. It may be seen from the diagram that the data points are generally distributed near the linear fitting curve, indicating the model has high prediction precision and small error for methanol concentration. It shows that by infrared thermography combining neural network analysis, we may accurately estimate the concentration of methanol in the mixtures.

FIG. 12 shows prediction results of ethanol concentration, wherein the horizontal axis represents the real concentration (vol %), and the vertical axis represents predicted concentration (vol %). Similarly, the data points are distributed around the linear fitting curve, with small error bars, showing that the model is also highly accurate for ethanol concentration. It means that despite possible impact of the mixtures on the infrared thermography signal, the neural network still learns ethanol characteristics effectively, and separates the characteristics from the mixture signal, to implement precise quantitative analysis.

FIG. 13 demonstrates concentration predictions of acetone across different mixing ratios, wherein the horizontal axis is the real concentration (vol %), and the vertical axis is the predicted concentration (vol %). The data points are still distributed tightly around the linear fitting curve, and the range of the error bars shows that the model may provide stable prediction results in most cases. Overall, the concentration prediction results for methanol, ethanol, and acetone all exhibit good linear correlation, indicating that our detection system 100 may not only perform substance classification, but also implement quantitative concentration analysis for components in a mixture.

The experiment demonstrates a novel substance detection method for the artificial intelligence composite mixture detection system 100 based on a thermal emission chip 20. From pure substance characteristics analysis, to mixture classification and identification, and then to concentration prediction, the experimental results show that this method enables to precisely identify and quantitatively analyze each component in a mixture. FIG. 7-FIG. 10 show FTIR spectra, thermal emission characteristics data, and confusion matrices of classification results, indicating that the machine learning model successfully implements substance classification based on thermography data, maintaining high correctness even in mixture systems. The second row demonstrates concentration prediction for each component in a mixture, with prediction data closely matching real concentration, with small error, showing that this method may replace conventional spectroscopic measurement, and perform non-contact concentration detection. This study proves that combining a thermal emission chip 20, thermography, and machine learning enables to implement precise infrared detection, offers new solutions for low-cost, portable substance detection, and has a wide range of potential applications, for example in fields such as bioassay, environmental monitoring, and food safety analysis, etc. The embodiment proposes a concentration prediction method based on a thermal emission chip and a 1D convolutional neural network (1D-CNN) model, aiming to provide accurate concentration prediction based on a mapping relationship between spectral features and sample concentrations. In the experiment, the thermal emission chip is first heated using the heating platform, to generate a broad-spectrum infrared thermal emission signal. A sample to be tested is placed on the chip array, and the infrared signal interacts with the sample and corresponding spectral data are generated. The change in the radiation from the sample is captured in real time by the infrared camera 30, to generate multi-dimensional data. Background signals are collected for correction, and standardized processing is performed on sample signals, to ensure data consistency. Normalized signal data are input into the 1D-CNN model, and the model extracts radiation temperature features through multi-layer convolution and the pooling layer, to learn a relationship between data features and sample concentration. Ultimately, the AI model 40 may accurately predict concentration of respective components in the sample. Experimental results are shown in FIG. 7-FIG. 13, wherein mean values and error bars of concentration prediction of the three components in the mixture are plotted in the figures.

To verify the advantages of the methods in the present disclosure, a comparative experiment is designed, which compares performance of a conventional FTIR infrared spectrometer with that of the system based on a thermal emission chip in substance classification and concentration prediction of 50 substances. In the substance classification task, the conventional method achieves high accuracy in single substance identification, because of the possibility of comparison with standard spectra, however in spectroscopic measurement of three mixtures, due to spectral overlap, it is difficult to distinguish for classification and mixed concentration prediction of components with similar concentration. Experimental results show that the method of the present disclosure exhibits significant advantages in correctness of both substance classification and concentration prediction, verifying efficiency and accuracy of the metasurface chip combining the 1D-CNN model.

Herein, those skilled in the art should recognize that although a plurality of illustrative embodiments of the present disclosure have been illustrated and described in detail, numerous other variations or modifications consistent with the principles of the present disclosure may be directly determined or derived based on the present disclosure without departing from the spirit and scope thereof. Therefore, the scope of the present disclosure should be understood and construed as encompassing all such other variations or modifications.

What is claimed is:

1. A construction method for an artificial intelligence composite mixture detection system based on a thermal emission chip, characterized in that the method comprises:
preparing a thermal emission chip, and constructing an artificial intelligence model based on the thermal emission chip;
sequentially placing different standard samples between the thermal emission chip and an infrared camera, and heating the thermal emission chip, such that the infrared camera acquires reaction signal data produced when thermal emission emitted by the thermal emission chip is absorbed by the respective different standard samples; and
inputting the reaction signal data of the different standard samples into the artificial intelligence model, to adjust a parameter of the artificial intelligence model, to train the artificial intelligence model.

2. The construction method according to claim 1, further comprising: after the preparing a thermal emission chip, and constructing an artificial intelligence model based on the thermal emission chip,
heating the thermal emission chip, and acquiring background signals for the thermal emission chip not originating from the standard samples;
correcting reaction signals of the different standard samples using the background signals, to obtain the corrected reaction signal data;
training the artificial intelligence model using the corrected reaction signal data, to obtain a trained model.

3. The construction method according to claim 2, characterized by constructing the artificial intelligence model by:
constructing a first Conv1D layer, the first Conv1D layer being configured to extract local features of the corrected reaction signal data;
constructing a MaxPooling1D layer, the MaxPooling1D layer being configured to perform dimensionality reduction on the local features;
constructing a second Conv1D layer, the second Conv1D layer being configured to enhance capability of extracting the local features;
flattening, using a Flatten layer, two-dimensional feature maps of the local features into a one-dimensional vector;
constructing a Dense layer, the Dense layer being configured to integrate feature information of the local features; and
constructing an output layer, the output layer being configured to output detection results for components of the standard samples and prediction results of concentrations of the components.

4. The construction method according to claim 1, characterized by preparing the thermal emission chip by:
constructing a model of a metasurface array;
simulating the model of the metasurface array using a simulation software, to obtain a target thickness parameter of a respective layer of material in the model of the metasurface array; and
preparing the thermal emission chip based on the target thickness parameter of the respective layer of material.

5. The construction method according to claim 4, wherein the preparing the thermal emission chip based on the target thickness parameter of the respective layer of material comprises:
providing a substrate;
depositing a metal layer on the substrate, wherein the metal layer serves as a reflective substrate;
sequentially preparing a spacer layer and a silicon layer on the metal layer through magnetron sputtering or chemical vapor deposition, wherein the spacer layer is located between the metal layer and the silicon layer; and
performing micro-nanofabrication on the silicon layer using lithography or etching processes, thereby preparing and obtaining the thermal emission chip having the metasurface array.

6. The construction method according to claim 5, wherein the performing micro-nanofabrication on the silicon layer using lithography or etching processes, thereby preparing and obtaining the thermal emission chip having the metasurface array comprises:
simulating a period of the metasurface array on the silicon layer and diameters and heights of silicon nanopillars using the simulation software, to select a target period as well as target diameters and target heights of the silicon nanopillars; and
performing micro-nanofabrication on the silicon layer using lithography or etching processes based on the target period as well as the target diameters and the target heights of the silicon nanopillars, thereby preparing and obtaining the thermal emission chip having the metasurface array.

7. The construction method according to claim 2, wherein in the inputting the reaction signal data of the different standard samples into the artificial intelligence model, to adjust a parameter of the artificial intelligence model, to train the artificial intelligence model, the corrected reaction signal data are divided into a training set and a test set, wherein the training set is configured to train the artificial intelligence model, and the test set is configured to test the artificial intelligence model.

8. The construction method according to claim 4, wherein the simulating the model of the metasurface array using a simulation software, to obtain a target thickness parameter of a respective layer of material in the model of the metasurface array comprises:
adjusting parameters comprising a metal layer, a spacer layer, heights of silicon nanopillars as variables in the simulation software by systematically scanning parameter combinations for respective layers, to identify an optimal layer thickness combination based on obtained electromagnetic resonance modes and absorption peak positions.

9. The construction method according to claim 5, comprising: after the performing micro-nanofabrication on the silicon layer using lithography or etching processes, thereby preparing and obtaining the thermal emission chip having the metasurface array,
cleaning and drying the thermal emission chip.

10. The construction method according to claim 6, wherein the simulating a period of the metasurface array on the silicon layer and diameters and heights of silicon nanopillars using the simulation software, to select a target period as well as target diameters and target heights of the silicon nanopillars comprises:
tuning absorption peak positions and optimizing absorption intensity by adjusting a proportional parameter of geometric dimensions of the thermal emission chip.

11. The construction method according to claim 6, wherein the simulating a period of the metasurface array on the silicon layer and diameters and heights of silicon nanopillars using the simulation software, to select a target period as well as target diameters and target heights of the silicon nanopillars comprises:
comparing simulation results with experimental results, and performing iterative optimization on geometric parameters of the thermal emission chip, until absorption peak coverage is achieved within a target wavelength band.

12. The construction method according to claim 10, wherein the tuning absorption peak positions and optimizing absorption intensity by adjusting a proportional parameter of geometric dimensions of the thermal emission chip comprises:
tuning the absorption peak positions by simultaneously scaling the diameters of the silicon nanopillars and the period by a same proportion.

13. An artificial intelligence composite mixture detection system based on a thermal emission chip, applied to the construction method according to claim 1, the system comprising:
a heating device;
a thermal emission chip, provided on one side of the heating device, wherein the thermal emission chip is configured to generate, when heated by the heating device, infrared thermal emission signals having preset radiation characteristics;
an infrared camera, provided on a side of the thermal emission chip facing away from the heating device, wherein a standard sample is placed between the thermal emission chip and the infrared camera, and the infrared camera is configured to acquire a signal produced by an absorption reaction between the infrared thermal emission signals and the standard sample, and process the signal to generate data packets; and
an artificial intelligence model based on the thermal emission chip, provided on a side of the infrared camera facing away from the thermal emission chip, wherein the artificial intelligence model is configured to receive the data packets, detect a component of the standard sample based on the data packets, and predict a concentration of the component.

14. The artificial intelligence composite mixture detection system based on a thermal emission chip according to claim 13, wherein the construction method further comprises: after the preparing a thermal emission chip, and constructing an artificial intelligence model based on the thermal emission chip,
heating the thermal emission chip, and acquiring background signals for the thermal emission chip not originating from the standard samples;
correcting reaction signals of the different standard samples using the background signals, to obtain the corrected reaction signal data;
training the artificial intelligence model using the corrected reaction signal data, to obtain a trained model.

15. The artificial intelligence composite mixture detection system based on a thermal emission chip according to claim 14, characterized by constructing the artificial intelligence model by:
constructing a first Conv1D layer, the first Conv1D layer being configured to extract local features of the corrected reaction signal data;
constructing a MaxPooling1D layer, the MaxPooling1D layer being configured to perform dimensionality reduction on the local features;
constructing a second Conv1D layer, the second Conv1D layer being configured to enhance capability of extracting the local features;
flattening, using a Flatten layer, two-dimensional feature maps of the local features into a one-dimensional vector;
constructing a Dense layer, the Dense layer being configured to integrate feature information of the local features; and
constructing an output layer, the output layer being configured to output detection results for components of the standard samples and prediction results of concentrations of the components.

16. The artificial intelligence composite mixture detection system based on a thermal emission chip according to claim 13, characterized by preparing the thermal emission chip by:
constructing a model of a metasurface array;
simulating the model of the metasurface array using a simulation software, to obtain a target thickness parameter of a respective layer of material in the model of the metasurface array; and
preparing the thermal emission chip based on the target thickness parameter of the respective layer of material.

17. The artificial intelligence composite mixture detection system based on a thermal emission chip according to claim 16, wherein the preparing the thermal emission chip based on the target thickness parameter of the respective layer of material comprises:
providing a substrate;
depositing a metal layer on the substrate, wherein the metal layer serves as a reflective substrate;
sequentially preparing a spacer layer and a silicon layer on the metal layer through magnetron sputtering or chemical vapor deposition, wherein the spacer layer is located between the metal layer and the silicon layer; and
performing micro-nanofabrication on the silicon layer using lithography or etching processes, thereby preparing and obtaining the thermal emission chip having the metasurface array.

18. The artificial intelligence composite mixture detection system based on a thermal emission chip according to claim 17, wherein the performing micro-nanofabrication on the silicon layer using lithography or etching processes, thereby preparing and obtaining the thermal emission chip having the metasurface array comprises:
simulating a period of the metasurface array on the silicon layer and diameters and heights of silicon nanopillars using the simulation software, to select a target period as well as target diameters and target heights of the silicon nanopillars; and
performing micro-nanofabrication on the silicon layer using lithography or etching processes based on the target period as well as the target diameters and the target heights of the silicon nanopillars, thereby preparing and obtaining the thermal emission chip having the metasurface array.

19. The artificial intelligence composite mixture detection system based on a thermal emission chip according to claim 14, wherein in the inputting the reaction signal data of the different standard samples into the artificial intelligence model, to adjust a parameter of the artificial intelligence model, to train the artificial intelligence model, the corrected reaction signal data are divided into a training set and a test set, wherein the training set is configured to train the artificial intelligence model, and the test set is configured to test the artificial intelligence model.

20. The artificial intelligence composite mixture detection system based on a thermal emission chip according to claim 16, wherein the simulating the model of the metasurface array using a simulation software, to obtain a target thickness parameter of a respective layer of material in the model of the metasurface array comprises:
adjusting parameters comprising a metal layer, a spacer layer, heights of silicon nanopillars as variables in the simulation software by systematically scanning parameter combinations for respective layers, to identify an optimal layer thickness combination based on obtained electromagnetic resonance modes and absorption peak positions.
